(19) United States
(12) Patent Application Publication
(10) Pub. No.: US 2017/0095808 A1
(43) Pub. Date: Apr. 6, 2017

(54) Titanium Dioxide Layer With Improved Surface Properties

(71) Applicant: Siemens Aktiengesellschaft, Muenchen (DE)

(72) Inventors: Florian Eder, Erlangen (DE); Hans-Dieter Feucht, Renningen (DE); Rudolf Gensler, The Sterling (SG)

(73) Assignee: Siemens Aktiengesellschaft, Muenchen (DE)

(21) Appl. No.: 15/383,334

(22) Filed: Dec. 19, 2016

Related U.S. Application Data
(63) Continuation of application No. 12/377,289, filed on Apr. 15, 2010, now abandoned.

(30) Foreign Application Priority Data
Aug. 17, 2006 (DE) 10 2006 038 585.3

(51) Int. Cl. B01J 37/02; H01J 37/32; B01J 21/06; C09D 1/00; B01J 35/00

(52) U.S. Cl. CPC B01J 37/0217; C09D 1/00; B01J 35/002; B01J 21/063; H01J 37/32009; H01J 2237/334

(57) ABSTRACT

In a thermocatalytically active titanium dioxide coating, based on a sol-gel system, the titanium dioxide coating contains a structuring component and/or is produced by a structuring method.

### CROSS-REFERENCE TO RELATED APPLICATIONS

This application is a U.S. National Stage Application of International Application No. PCT/EP2007/058406 filed Aug. 14, 2007, which designates the United States of America, and claims priority to German Patent Application No. 10 2006 038 585.3 filed Aug. 17, 2006. The contents of these applications are incorporated herein in their entirety by this reference.

### TECHNICAL FIELD

The invention relates to titanium dioxide layer with improved surface properties.

### BACKGROUND

In the case of many applications in the automotive industry and in power plant technology, dirt deposits (hydrocarbons, oils, dust, etc.) adversely affect the functioning of components such as for example sensors, injectors, valves, turbines or gas and air compressors in a lasting manner.

As a result, it was therefore proposed to provide such components, which are typically exposed during operation to temperatures ranging from 200° to 600° with coatings, which have a thermally induced self-cleaning effect. In many cases, it must be taken into account that significant improvements with regard to reliability, service life, reduction of harmful substance emissions and increasing the degree of efficiency are achieved in this way.

However, it has been proven that the available coatings are often less suitable for the thermally induced degradation of organic deposits and only a few of such coatings are available at present.

A plurality of coatings used in the prior art are based on metal oxides. In this way, for example, vanadium pentoxide coatings from DE 101 3067 3 for intake valves in combustion engines are well known.

DE 199 153 77 describes a mixture of transition metal oxides (manganese, cobalt, cerium) for deodorization.

As the photocatalytic active material, titanium dioxide is described in D. Bahnemann “Photocatalytic water treatment—solar energy applications”, Solar Energy (2004), Vol. 77, pp. 445. 459.

### SUMMARY

According to various embodiments a titanium dioxide coating can be provided, which is in the position to also work thermally induced catalytically.

According to an embodiment, a thermocatalytically active titanium dioxide coating, based on a sol-gel system, may comprise at least one structuring component and/or was produced by means of at least one structuring method.

According to a further embodiment, the titanium dioxide coating can be applied to a prestructured substrate. According to a further embodiment, the roughness of the prestructured substrates may range from ≧50 nm to ≦100 μm. According to a further embodiment, the prestructured substrate may have been prestructured by means of stamping, rolling and/or a wet-chemical and/or a plasma etching process. According to a further embodiment, the titanium dioxide coating may contain structuring metal oxide particles. According to a further embodiment, the structuring particles may have an average particle size ranging from ≧50 nm to ≦50 μm. According to a further embodiment, the structuring particles may be selected from a material containing SiO₂, Al₂O₃, ZrO₂, TiO₂, boehmite (α-AlO(OH)), silicate layers, CeO₂, Fe₂O₃, MnO, Mn₃O₄ or mixtures thereof. According to a further embodiment, the titanium dioxide coating may be applied to a prestructured substrate, which is provided with structuring particles as described above. According to a further embodiment, the titanium dioxide coating may be produced by means of a sol-gel method and applied by means of a wet-chemical method.

According to another embodiment, a method for producing a thermocatalytically active titanium dioxide coating, may be based on a sol-gel process and may include at least one structuring step and/or the addition of at least one structuring component.

According to a further embodiment of the method, the titanium dioxide coating can be applied to a prestructured substrate, in particular as described above. According to a further embodiment of the method, the method may comprise the addition of structuring metal oxide particles, in particular as described above. According to a further embodiment of the method, the titanium can be added in the form of a titanium alkoxide precursor solution. According to a further embodiment of the method, the viscosity of the titanium-containing precursor solution may be from ≧1 mPa*s to ≦10,000 mPa*s. According to a further embodiment of the method, the titanium-containing precursor solution in addition may contain at least one complexing agent. According to a further embodiment of the method, the at least one complexing agent can be selected from the group ethers, polyethers, substituted polyethers, non-ionic tensides, amines, alkanolamines or mixtures thereof. According to a further embodiment of the method, the pH value of the titanium-containing precursor solution can be from ≧0 to ≦3.

According to yet another embodiment, a titanium dioxide coating as described above and/or of a titanium dioxide coating, produced as described above may be applied for
Sensors,
Injectors,
Valves,
Turbines,
Gas compressors and air compressors,
Domestic appliances, in particular ovens and stoves.

### BRIEF DESCRIPTION OF THE DRAWINGS

Further details, features and advantages of the subject matter of the invention arise from the description below of the accompanying drawing, in which—for example—an exemplary embodiment of a titanium dioxide coating is shown, in which:

FIG. 1 shows two steel substrates with and without a TiO₂ coating after an attempt to remove paraffin wax.

### DETAILED DESCRIPTION

Accordingly, a thermocatalytically active titanium dioxide coating based on a sol-gel system is proposed, characterized in that the titanium dioxide coating contains at least one structuring component and/or is produced by means of at least one structuring method.

The designation “titanium dioxide coating” in the sense of the present invention means or includes in particular that the coating—excluding the possibly available at least one structuring component—contains titanium dioxide as the main component. In this process, ≧70%, even more preferably ≧80%, as well as most preferred ≧90% to ≦100 of the coating consists of titanium dioxide.

The designation “based on a sol-gel system” in the sense of the present invention means or includes in particular, that the titanium dioxide coating is produced by means of a method which contains a sol-gel phase, in particular and in this respect preferably by means of a method shown below.

The designation “structuring component” in the sense of the present invention means or includes in particular each component which is in the position to increase the active surface of the titanium dioxide coating.

The designation “structuring method” in the sense of the present invention means or includes in particular that the titanium dioxide coating is produced by means of a method which contains a structuring phase, by means of which in particular and in this respect preferably the active surface of the titanium dioxide coating is increased.

By means of such a titanium dioxide coating in accordance with various embodiments, one or a plurality of the following advantages can be achieved in many applications within the present invention:
Compared to catalytic converters, which are based on precious metal components, the coating in accordance with various embodiments is characterized by a simple and material-saving production and application, which avoids complicated processes such as vacuum coatings (CVD/PVD).
A subsequent coating of large substrates (for example components of compressors in power plants) on site is possible in many cases.
In many applications, the thickness of the titanium dioxide coating produced amounts to a few micrometers at the most. As a result, it is largely unaffected by thermal stress and influences component dimensions and tolerances only insignificantly.

An embodiment is characterized in that the titanium dioxide coating is applied to a prestructured substrate. This has turned out to be suitable for a large series of applications within the present invention because in this way a titanium dioxide coating in accordance with the invention can be obtained in a particularly simple manner in many cases.

The designation “prestructured” may include that the substrate, to which the titanium dioxide coating in accordance with various embodiments is applied, was in particular structured in process steps as is explained below.

In the case of some applications (such as for example the following example, without being limited thereto) it was however found that the substrate could already have been prestructured “automatically by itself” in a suitable manner. However, this must mostly be established before the titanium dioxide coating in accordance with various embodiments is applied.

An embodiment is characterized in that the roughness of the prestructured substrate ranges from ≧50 nm to ≦100 μm. In many cases and applications within the present invention it has turned out that such a roughness is particularly suitable for achieving a titanium dioxide coating in accordance with the invention.

Preferably, the roughness of the prestructured substrate ranges from ≧100 nm to ≦50 μm, more preferably ≧200 nm to ≦10 μm.

An embodiment is characterized in that the prestructured substrate was prestructured by means of stamping, rolling and/or a wet-chemical and/or a plasma etching process. This is in particular preferred in the case of many applications of the present invention in the case of which the substrate is not prestructured “automatically by itself” in a suitable manner.

An embodiment is characterized in that the titanium dioxide coating contains structuring metal oxide particles. It has been found in the case of many applications within the present invention that in this way a titanium dioxide coating in accordance with the invention can be achieved in a particularly simple manner.

The designation “structuring metal oxide particle” in the sense of the present invention means or includes in particular all metal oxides in particle form, which are in the position to increase the active surface of the titanium dioxide coating.

In this process, the (molar) ratio of metal oxide to titanium dioxide is preferably from ≧1:1 to ≦1000:1, more preferably from ≧10:1 to ≦100:1. This has proven favorable for many applications in the various embodiments.

An embodiment is characterized in that the structuring particles have an average particle size ranging from ≧50 nm to ≦50 μm. This has particularly proven favorable for many applications in the present invention.

The structuring particles preferably have an average particle size ranging from ≧80 nm to ≦20 μm, more preferably ≧100 nm to ≦10 μm.

An embodiment is characterized in that the structuring particles are selected from a material containing SiO₂, Al₂O₃, ZrO₂, TiO₂, boehmite (α-AlO(OH)), silicate layers, CeO₂, Fe₂O₃, MnO, Mn₃O₄ or mixtures thereof.

An embodiment is characterized in that the titanium dioxide coating is applied to a prestructured substrate, which is supplied with structuring particles, in particular structuring metal oxide particles, preferably as described within the present invention.

The designation “structuring particles” in the sense of the present invention means or includes in particular all materials in particle form which are in the position to increase the active surface of the titanium dioxide coating.

An embodiment is characterized in that the prestructured substrate is provided with particles containing a material selected from the group SiO₂, Al₂O₃, ZrO₂, TiO₂, boehmite (α-AlO(OH)), silicate layers, CeO₂, Fe₂O₃, MnO, Mn₃O₄ or mixtures thereof.

In this process, the (molar) ratio of structuring particles to titanium dioxide is preferably from ≧1:1 to ≦1000:1, more preferably from ≧10:1 to ≦100:1. This has proven favorable for many applications in the present invention.

An embodiment is characterized in that the structuring particles have an average particle size ranging from ≧50 nm to ≦50 μm. This has particularly proven favorable for many applications in the present invention.

Preferably, the structuring particles have an average particle size ranging from ≧80 nm to ≦20 μm, more preferably ≧100 nm to ≦10 μm.

Surprisingly it was found that a substrate prestructured in this way is able, not only in the case of systems based on TiO₂ coatings, to increase the properties of these coatings, but also in the case of coatings based on other materials. The use of structuring particles, in particular as described in the present invention, on a prestructured substrate is therefore of intrinsic inventive importance.

In this way, within this embodiment, which has proven favorable for many applications, not titanium dioxide but the substrate and/or the TiO₂ precursor solution is provided with structuring particles. However, every person skilled in the art will immediately see that also a combination of the substrate, which has particles such as titanium dioxide, which has particles, is possible in the invention and likewise represents an embodiment.

An embodiment is characterized in that the titanium dioxide coating solution is prepared by means of a sol-gel method and applied by means of a wet-chemical method.

The designation “sol-gel method” in the sense of the present invention means or includes in particular all methods in the case of which metal precursor materials, in particular metal halides and/or metal alkoxides, are subjected in solution to hydrolysis and subsequent condensation.

In addition, the other embodiments relate to a method for producing a thermocatalytically active titanium dioxide coating, characterized in that the method is based on a sol-gel process and includes at least one structuring step and/or the addition of at least one structuring component.

The designation “sol-gel process” in the sense of the present invention means or includes in particular all the processes and/or methods in the case of which metal precursor materials, in particular metal halides and/or metal alkoxides, are subjected in solution to hydrolysis and subsequent condensation.

An embodiment of the method for producing a thermocatalytically active titanium dioxide coating is characterized in that the titanium dioxide coating is applied to a prestructured substrate, in particular in accordance with the above-described embodiments.

An embodiment of the method for producing a thermocatalytically active titanium dioxide coating is characterized by means of the addition of structuring metal oxide particles, in particular structuring metal oxide particles in accordance with the above-described embodiment.

An embodiment of the method for producing a thermocatalytically active titanium dioxide coating is characterized in that the titanium is added in the form of a titanium alkoxide precursor solution.

In accordance with an embodiment, the concentration of titanium in the titanium precursor solution is ≧0.004 mol to ≦0.2 mol titanium precursor to 1 mol solvent. This has proven favorable for producing coatings within a wider range of applications of the present invention.

More preferably, the concentration of titanium in the titanium precursor solution is ≧0.02 mol to ≦0.1 mol titanium precursor to 1 mol solvent.

General group definition: Within the description and the claims, general groups such as for example: alkyl, alkoxy, aryl etc. are used and described. Unless otherwise described, the following groups are preferably used in the generally described groups within the scope of this invention:
Alkyl: linear and branched C1-C8 alkyls,
Long-chain alkyls: linear and branched C5-C20 alkyls,
Alkenyl: C2-C6 alkenyl,
Cycloalkyl: C3-C8 cycloalkyl,
Alkoxide/alkoxy: C1-C6 alkoxy, linear and branched,
Long-chain alkoxide/alkoxy: linear and branched C5-C20 al-koxy
Polyether: selected from the group containing H—(O—CH₂—CH(R))ₙ—OH and H—(O—CH₂—CH(R))ₙ—H, where R is independently selected from: hydrogen, alkyl, aryl, halogen and n is from 1 to 250
Substituted polyether: selected from the group containing R₂—(O—CH₂—CH(R₁))ₙ—OR₃ and R₂—(O—CH₂—CH(R₂))ₙ—R₃, where R₁, R₂, R₃ are independently selected from: hydrogen, alkyl, long-chain alkyls, aryl, halogen and n is from 1 to 250
Amine: the group N(R)3, where each R is independently selected from: hydrogen; C1-C6 alkyl; C1-C6 alkyl C6H5;
Alcohol amine: the group N(R)3, where each R is independently selected from: hydrogen, —(CR₁R₂)ₙ—OH, where each R₁ and R₂ is independently selected from the group containing hydrogen, halogen, alkyl and n is from 1 to 6.
Ether: The connection R₁—O—R₂, where each R₁ and R₂ is independently selected from the group containing hydrogen, halogen, alkyl, cycloalkyl, aryl and long-chain alkyl.

Unless mentioned otherwise, the following groups are more preferred groups within the general group definition:
Alkyl: linear and branched C1-C6 alkyl,
Alkenyl: C3-C6 alkenyl,
Cycloalkyl: C6-C8 cycloalkyl,
Alkoxy, alkoxide: C1-C4 alkoxy, in particular isopropyloxide
Long-chain alkoxy: linear and branched C5-C10 alkoxy, but preferably linear C6-C8 alkoxy
Polyether: selected from the group containing H—(O—CH₂—CH(R))ₙ—OH and H—(O—CH₂—CH(R))ₙ—H, where R is independently selected from: hydrogen, alkyl, aryl, halogen and n is from 10 to 100, preferably 25 to 50
Substituted polyether: selected from the group containing R₂—(O—CH₂—CH(R₁))ₙ—OR₃ and R₂—(O—CH₂—CH(R₂))ₙ—R₃, where R₁, R₂, R₃ are independently selected from: hydrogen, alkyl, long-chain alkyls, aryl, halogen and n is from 10 to 100, preferably 25 to 50

An embodiment of the method for producing a thermocatalytically active titanium dioxide coating is characterized in that the viscosity of the titanium-containing precursor solution ranges from ≧1 mPa*s to ≦10,000 mPa*s, but preferably ≧10 mPa*s to ≦1,000 mPa*s. This has proven favorable for many applications in the present invention.

An embodiment of the method for producing a thermocatalytically active titanium dioxide coating is characterized in that the titanium-containing precursor solution in addition contains at least one complexing agent.

The designation “complexing agent” in the sense of the present invention means or includes in particular all materials which are in the position to keep, on their own or in combination with other materials, titanium at a concentration ranging from 0.2 mol titanium to 1 mol solvent in the titanium-containing precursor solution at a pH of <3, preferably <1 in solution.

Preferably, the molar ratio of complexing agent to titanium is 0.01 mol to 4 mol complexing agent to 1 mol titanium. This has proven favorable for many applications in the present invention. More preferably, the molar ratio of complexing agent is 0.02 mol to 0.1 mol complexing agent to 1 mol titanium.

An embodiment of the method for producing a thermocatalytically active titanium dioxide coating is characterized in that the at least one complexing agent is selected from the group ethers, polyethers, substituted polyethers, non-ionic tensides, amines, alcohol amines or mixtures thereof.

An embodiment of the method for producing a thermocatalytically active titanium dioxide coating is characterized in that the pH value of the titanium-containing precursor solution is from ≧0 to ≦3, preferably ≧1 to ≦2.

In addition, the present invention relates to the use of a titanium dioxide coating in accordance with the present invention and/or a titanium dioxide coating, produced according to the method in accordance with the invention for
Sensors,
Injectors,
Valves,
Turbines,
Gas compressors and air compressors,
Domestic appliances, in particular ovens and stoves

The aforementioned components as well as the components used and described in the examples of application and which are to be used in accordance with the invention are not subject to any particular exceptions as regards their size, shaping, choice of material and technical design, so that the selection criteria in the area of application can be used without restrictions.

### EXAMPLE I

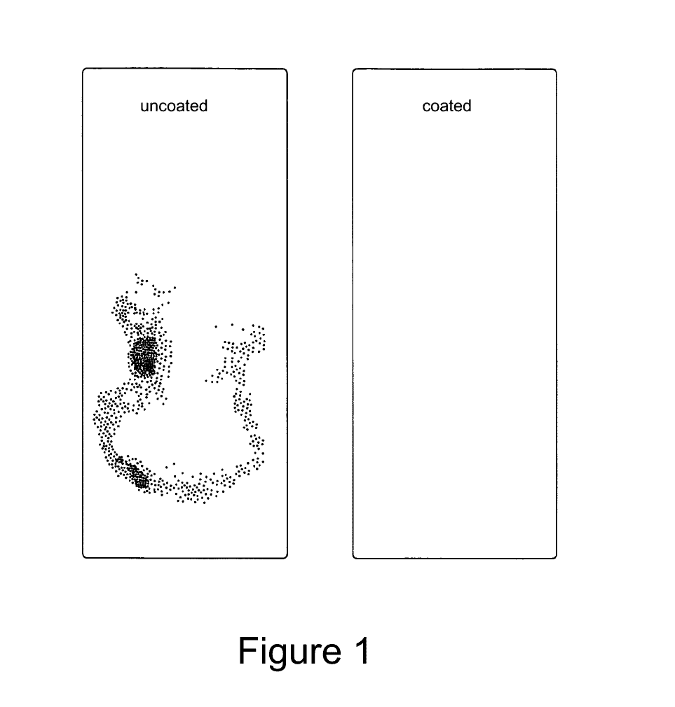

FIG. 1 relates to the example I below, in the case of which—purely illustratively and not restrictively—a titanium dioxide coating was produced as follows:

1 mol titanium isopropoxide was dissolved at room temperature in 16 mol isopropanol (IPA) and stirred for 1 h. 25 g Brij 56. (Aldrich) were dissolved in 2 mol IPA in the sonar bath and stirred slowly into the solution. After stirring for 3 h, a solution of 200 g 5-molar HCl and 4 mol IPA were added in a dropwise manner while stirring and stirred for another hour. The solution obtained was applied to a steel substrate by means of immersion. It was beforehand determined by means of surface measurement that the substrate was prestructured in the sense of the present invention.

After the drying process at room temperature, the layer was tempered for 10 minutes at 400° C.

An organic test solution (saturated solution of paraffin wax in toluene) was applied by means of dropping onto the platelets, the solvent evaporated in air and the platelets put in an oven at a temperature of 400° C. for 10 minutes.

In FIG. 1, an uncoated reference sample can be seen on the left; the righthand sample shows the coated steel substrate.

The uncoated sample (FIG. 1 left) clearly shows the remaining organic residues, while the coated area of the righthand sample shows no residues. In addition, the coating prevents an oxidation of the underlying metal surface (no tempering colors).

1-20. (canceled)

21. A method of forming a thermocatalytically active coating, based on a sol-gel system, the method comprising:
providing a substrate;
prestructuring the substrate by performing at least one of a stamping process, a rolling process, a wet-chemical process, or a plasma etching process to the substrate;
forming a titanium dioxide coating by a process including adding metal oxide structuring particles to a volume of titanium dioxide, wherein the metal oxide structuring particles are selected from the group of metal oxides consisting of SiO2, Al2O3, ZrO2, TiO2 boehmite (α-AlO(OH)), CeO2, Fe2O3, MnO, and Mn3O4; and
subsequent to the prestructuring of the substrate, applying the titanium dioxide coating, including the added metal oxide structuring particles, to the prestructured substrate;
wherein the molar ratio of metal oxide particles to titanium dioxide in the titanium dioxide coating is ≧1:1 and ≦1000:1.

22. (canceled)

23. The method of claim 21, wherein the prestructured substrate has a roughness in a range from ≧50 nm to ≦100 μm.

24. The method of claim 21, wherein the metal oxide structuring particles have an average particle size ranging from ≧50 nm to ≦50 μm.

25. The method of claim 21, wherein the metal oxide structuring particles have an average particle size ranging from ≧100 nm to ≦10 μm.

26. The method of claim 21, wherein the metal oxide structuring particles further comprise a metal oxide selected from the group of oxides consisting of SiO2, Fe2O3, and mixtures thereof.

27. The method of claim 21, wherein the metal oxide structuring particles further comprise SiO2.

28. The method of claim 21, comprising:
producing the thermocatalytically active coating using a sol-gel method;
applying the thermocatalytically active coating using a wet-chemical method.

29. The method of claim 21, wherein the prestructured substrate comprises a component surface structure of a sensor, an injector, a valve, a turbing, a gas compressor, an air compressor, an oven, a stove, or other domestic appliance; and
wherein the method includes applying the titanium dioxide coating to the component surface structure.

30. (canceled)

31. The method of claim 21, comprising adding the titanium in the form of a titanium alkoxide precursor solution.

32. The method of claim 31, wherein the viscosity of the titanium-containing precursor solution is from ≧1 mPa*s to ≦10,000 mPa*s.

33. The method of claim 31, wherein the titanium-containing precursor solution contains at least one complexing agent.

34. The method of claim 33, wherein the at least one complexing agent is selected from the group ethers, polyethers, substituted polyethers, non-ionic tensides, amines, alkanolamines or mixtures thereof.

35. The method of claim 31, wherein the pH value of the titanium-containing precursor solution is in the range of ≧0 to ≦3.
